(19) United States
(12) Patent Application Publication
(10) Pub. No.: US 2006/0113063 A1
(43) Pub. Date: Jun. 1, 2006

(54) Thin-plate microchannel structure

(76) Inventors: Lalit Chordia, Pittsburgh, PA (US); John C. Davis, Pittsburgh, PA (US); Stephan Fatschel, Seven Fields, PA (US); Robert Panella, New Kensignton, PA (US)

Correspondence Address: LALIT CHORDIA;THAR TECHNOLOGIES, 730 WILLIAM PITT WAY, PITTSBURGH, PA, 15238, US

(21) Appl. No.: 11/251,477

(22) Filed: Oct. 14, 2005

Related U.S. Application Data
(60) Provisional application No. 60/619,505, filed on Oct. 15, 2004.

(51) Int. Cl. H05K 7/20

(52) U.S. Cl. 165/80.4; 165/170; 361/699

(57) ABSTRACT

A thin-plate microchannel structure of channel depth of 500 microns or less and capable of withstanding pressure up to 6,000 psi inch is disclosed. The thin-plate microchannel structure may be formed from metal, ceramic or polymeric materials. It can be employed to facilitate the exchange of heat between a single fluid in liquid, gaseous or supercritical state and another device, such as an integrated circuit, with which it is near or in contact.

### CROSS-REFERENCE TO RELATED APPLICATION

This application claims priority from the United States provisional patent application of the same title, which was filed on Oct. 15, 2004 and was assigned U.S. patent application Ser. No. 60/619,505, teachings of which are incorporated herein by reference.

### BACKGROUND OF THE INVENTION

Recent advances in technology have emphasized a need for small chemical reactors or heat exchangers that contain microchannels. For purposes of this invention, a microchannel is defined as an enclosed passageway of any circular, ovate or polygonal cross-section, for which the maximum cross-sectional dimension is less than 1 millimeter. Microchannels are open at the ends to allow the flow of fluids through them.

Research on microchannel structures is already extensive. One large class of inventions involves single-piece extrusions, typically of aluminum, comprising channels less than 1 millimeter in cross-sectional width. Heat exchangers such as these are typically used in air conditioning systems, particularly automotive air conditioners.

The literature is also rich with multiple-piece constructions. These typically involve such fabrication methods as milling, photolithographic etching or laser etching, among other methods, for trench formation followed by adhesive bonding, diffusion bonding, brazing and other methods for capping over trenches. Johnson et al (European Patent 0212878) describe a multilevel plate-type cross-flow heat exchanger that comprises microchannels formed in steel or other metals. Channels are 0.5 to 1.5 millimeters in diameter. This invention is notable for its application of etched microchannels in a laminated stack. However, Johnson does not address the method of bonding the various laminates other than the welding of inlet/outlet headers along the outer perimeter. It is unlikely that this construction can withstand high pressure without delaminating internally.

Alternatively, many inventions have focused on methods that cut slots in thin layers, which are subsequently laid up in stacks and joined with one of the aforementioned bonding methods. These methods have been applied most commonly to cross-flow heat exchangers in which heat from one fluid is being exchanged with heat from another fluid. This is not the situation found in contact cooling that is typical of electronics applications. In these electronic cases, a single cooling fluid flows through a heat exchanger that is in direct contact with the heat source or casing of a heat source.

A key problem in bringing any microchannel structure to commercial reality is in connecting fluid inlets and outlets in a manner that is not so bulky as to defeat the design advantages of the thin structure itself. In U.S. Pat. No. 5,099,910, Walpole and Missaggia teach a means of installing one central inlet and two outlets on one level of a two-level structure, with holes arranged in such a way that fluid flows in opposite directions in adjacent channels, thereby reducing the temperature gradient for fluid entering and exiting the device. More elaborate manifolding systems have appeared since, but most employ a similar two- or even three-layer distribution system (U.S. Patent App. 2004/0104022, Kenny et al). As these manifolds become more complicated, however, heat exchangers tend to grow in thickness.

Many of the efforts made toward developing chemical micro-reactors have resulted in secondary concepts for microchannel heat exchangers. Chemical micro-reactors typically comprise catalytic surfaces. The materials for constructing such devices may be chosen primarily for the benefit of the reactor function, not for heat exchange. An example is U.S. Pat. No. 6,672,502, which describes microchannel heat exchangers formed from intermetallic materials, such as nickel-aluminum. Scant attention is paid to methods of sealing over channels so that they can withstand high pressure and guarantee against leaks.

Several examples of microchannel fabrication in silicon exist. This concept is attractive to designers of such items as laser diodes, allowing them to increase diode efficiency by increasing the duty cycle as a result of lower-temperature operation. Much of the effort in developing microchannels in silicon was focused on ways to optimize channel dimensions. Tuckerman and Pease (U.S. Pat. No. 4,450,472) presented precise equations for calculating channel depth and aspect ratio assuming laminar flow. Phillips et al (U.S. Pat. No. 4,894,709) later expanded on this concept to include equations for cases of turbulent flow. While these developments are of great theoretical significance in that they point the way to optimum design, the application of the guidelines contained therein may be defeated by practical considerations related to fabrication. For example, the aspect ratio can be limited by etch geometry: As a channel is etched deeper, walls become more concave and ultimately break through. There can also be a lower limit imposed on the aspect ratio so as to prevent the channel cover from caving in and blocking the channel altogether.

### BRIEF SUMMARY OF THE INVENTION

The present invention discloses a thin-plate structure consisting of: [i] two layers of material bonded together; [ii] microchannels of 500 microns or less; [iii] a total thickness that is less than 1.0 millimeter and; [iv] the capability of withstanding pressure up to 6,000 psi.

This present invention further discloses a method of constructing a thin-plate microchannel structure consisting of: [i] forming a pattern of microchannel trenches on a substrate and; [ii] bonding an unpatterned plate over the top of the patterned substrate.

### BRIEF DESCRIPTION OF THE DRAWINGS

FIG. 1 illustrates one embodiment of the present invention of a thin-plate microchannel structure, along with a cross-sectional detail of the microchannels contained therein.

FIG. 2 illustrates a typical cross-sectional pattern of microchannels.

FIG. 3 presents performance data for a thin-plate microchannel structure fabricated according to the present invention using carbon dioxide as a coolant.

FIG. 4 presents performance data for a thin-plate microchannel structure fabricated according to the present invention using water as a coolant.

### DETAILED DESCRIPTION

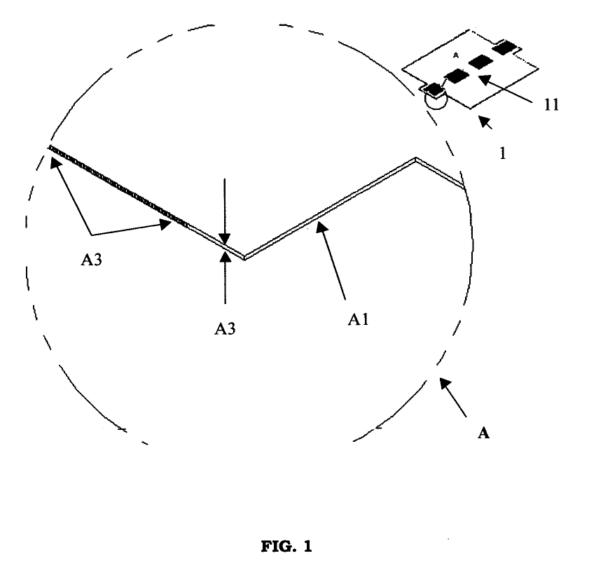

Referring to FIG. 1, a thin-plate microchannel structure of the present invention 1 is shown with cross-sectional detail A of a tab A1 that can serve as either the inlet or outlet. The thin-plate microchannel structure 1 is formed from the combination of any two materials from the group consisting of metallic, ceramic, polymeric materials or a combination thereof. In one preferred embodiment, microchannels A2 run through the plate and terminate at either end of the tabs. The path taken by the microchannels A2 is shown as a dotted gray area 11. The thickness of the thin-plate microchannel structure 1 is denoted by A3 and is 1 millimeter or less. In a preferred embodiment of the present invention, the total thickness of the thin-plate microchannel structure 1 is 500 micrometers or less. The thickness dimension is typically uniform over the entire area of the thin-plate microchannel structure 1, although there is no strict requirement that it be so. Length and width dimensions are highly variable, however. There is no requirement whatsoever that the microchannels A2 terminate in tab structures as shown in FIG. 1. Tab structures are but one configuration that may be applied for purposes of attaching fluid connectors to the thin-plate microchannel structure 1. Depending on the design of the connector, the microchannels A2 may terminate at such protruding tabs, or they may terminate along an edge that is flush with the primary edge; it is also possible to connect to the microchannels A2 through the top layer by means of a top-mounted connector, in which case there would be no appearance of microchannels A2 at the edges of the thin-plate microchannel structure 1.

Thus, FIG. 1 merely represents one example of a thin-plate microchannel structure for a printed circuit board configuration. What is common to all configurations, however, is the thin-plate microchannel structure's thin profile, which is less than 1 millimeter and preferably 10 mils or less. The thin-plate microchannel structure may be near or in direct contact with the device with which it is exchanging heat.

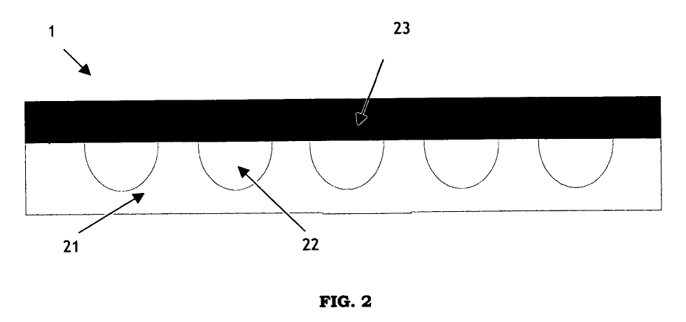

One preferred embodiment of the invention is shown in cross-sectional in FIG. 2. The thin-plate microchannel structure 1 consists of a substrate 21 onto which the microchannels 22 are formed and a top layer 23 that bonds to the unpatterned areas of the substrate 21 to form a capping layer above the microchannels 22. The microchannels 22 can be straight or meandering. The trenches may be formed by any of several methods known to the art of image transference onto surfaces. The path followed by the microchannels 22 might follow a pattern that is transferred from a drawing or photograph, as in the cases of photolithography and embossing.

Lamination of the thin-plate microchannel structure 1 within a printed circuit board, or on the top or bottom sides of a printed circuit board, are but one type of application as described in the current invention. Other configurations may include but are by no means limited to: the incorporation of the thin-plate microchannel structure within packaging systems for the integrated circuit itself; the incorporation into air-blown heat sinks as a means of supplementary cooling; the incorporation into chip-mounted heat sinks that are typically provided with the chip and installed separately from board-mounted chip packages; and even in racks, cases or other containers into which circuit boards are installed such as a computer casing.

The thin-plate microchannel structure of the present invention is formed in two steps: (1) opening trenches in a substrate; and (2) bonding of an unpatterned plate onto the substrate so as to enclose the trenches and form the microchannels. Step 1 can be accomplished by any of several means known in the art for scribing small trenches including, but not limited to, etching, laser scoring, computerizing numerical control (CNC) machining with a mill, pressing with an embossed die, or a combination thereof. For purposes of this invention, computerized numerical control can be any type of software program that directs the movement of a tool. In the preferred embodiment of the present invention, timed etching is practiced so as to form a trench without etching all the way through a substrate. The time interval chosen depends on factors known in the art of photolithography, including such variables as the etchant chemistry, thickness of the substrate, type of metal used in the substrate, etchant temperature and trench depth required.

Step 2 occurs after cleaning the substrate and making suitable preparations for proper registration of the unpatterned plate with the etched or scored substrate. This step can be accomplished by any of several means known in the art of bonding components to each other including, but not limited to, the use of adhesive interlayers, soldering, brazing, diffusion bonding or a combination thereof. In the preferred embodiment of the present invention, diffusion bonding is practiced without the use of a brazing-foil or plated interface: the substrate and unpatterned plate bond directly to each other.

Proper adherence to these requirements results in a thin-plate microchannel structure that is capable of withstanding internal pressure of up to 6,000 psi. The channel dimensions that are possible with said pressure and according to said fabrication requirements are up to 500 microns in depth, and preferably 200 microns in depth. The total thickness of a thin-plate microchannel structure of this configuration is no more than three times the channel depth.

Methods that employ an adhesive interlayer, brazing foil or solder present a potential risk of the interface material flowing into microchannels and plugging them. Diffusion bonding without a brazing-foil or plated interface avoids this possibility. Diffusion bonding involves heating the two components, and for this reason there is a possibility that either the unpatterned plate or the substrate material can itself flow into the microchannels. By following the guidelines listed below, a thin-plate microchannel structure can be fabricated with the desired characteristics disclosed above.

Dimensional Guideline 1: Bonding without an Interface Material
1: The sum of the ratios of: (a) the depth of a channel, as measured from the substrate surface to the deepest point in the channel, to the width of the channel as measured on the top surface of the substrate—also known as the channel aspect ratio—and (b) the thickness of the unpatterned plate to the width of the channel as measured on the top surface of the substrate, should be greater than or equal to 1.

In cases involving an interface material, such as an adhesive coating, solder or foil or plating material for brazing, Dimensional guideline 1 applies as well as this additional guideline:

Dimensional Guideline 2: Bonding with an Interface Material
2: The ratio of the thickness of the interface material to the depth of the microchannel, as measured from the top surface of the substrate to the deepest point in the channel, should be 0.33 or less and preferably 0.1 or less.

In the case of bonding with interface materials, it may be necessary to employ special means to ensure maximum thickness of the interface. According to a preferred embodiment of Dimensional Guideline 2, the maximum thickness is 0.4 mils for a 100-micron microchannel. In this and similar cases, it is permissible to calender a foil to the prescribed thickness, allowing for a reasonable degree of void formation and thickness irregularity in the calendered foil, as long as said voids occupy no more than 30% of the area of the foil, and as long as no single void is large enough that it would render a localized area of the bonded structure as subject to blistering and generalized bond failure. Foils may be avoided by plating the surface in advance of brazing, as long as the plating thickness conforms to this guideline.

There is a further guideline for ensuring the integrity of microchannel sidewalls in order to maintain separation between adjacent channels. This guideline applies if the channels are chemically etched, thereby ensuring that isotropic etching does not cause so much widening in the trenches below the top surface as to result in breaches in walls between adjacent channels.

Dimensional Guideline 3: Chemical Etching Microchannel Trenches in a Substrate:
3: The ratio of the cross-sectional distance between channels, as measured on the top surface of the substrate, to the depth of the channel as measured from the top surface of the substrate to the deepest point at the bottom of the channel, should be greater than 0.5.

Still another guideline addresses the question of pressurized channels. If pressure is a concern, as it would be in the case of cooling with supercritical or transcritical carbon dioxide, then Dimensional Guideline 4, below, should be applied before assessing Dimensional Guidelines 1-3, since it is a condition of pressure containment.

Dimensional Guideline 4: Pressure Containment
4: The thickness of the unpatterned plate, as well as the thickness as measured from the lowest point of the channel trench to the bottom of the substrate, must be sufficient to contain pressure within the channel in accordance with generally accepted standards of safety such as those defined by ASME pressure vessel code.

Because the minimum thickness of the unpatterned plate and the substrate bottom depend on materials of construction, pressure requirements and the geometric profile of the channels, Dimensional Guideline 4 will be met in most cases if the thickness of the unpatterned plate and substrate bottom are at least as much as the channel depth.

It is understood that the administration of the aforementioned Dimensional Guidelines in no way limits this disclosure as to the types of materials that might be employed in constructing a thin-plate microchannel structure. Concepts of channel flooding, and ways to avoid it, apply equally well to metals, adhesives and other bonding materials, as well as to the substrate and unpatterned plate materials themselves, were they to flow in some manner, such as melting, into the channel voids. Concepts of etching, scoring, milling or pressing, by any means chemical or physical, apply equally well to metals, ceramics and plastics. Concepts of bonding a substrate to an unpatterned plate also apply to all types of materials, although particular bonding methods apply more naturally to specific materials, as in the case of brazing applying to metallic materials, while adhesive bonding applies more generally to metals, ceramics and plastics.

The usefulness of the aforementioned dimensional guidelines is best judged in relation to prior teachings on channel sizing. For example, as previously mentioned, Tuckerman and Pease taught that under the assumption of laminar flow (which is warranted by the microscopic nature of the channels, 2:65) channel width and the distance between channels should be equal, and the ratio of channel depth to width for the particular case of water cooled silicon should be 8:1. While this may be optimum from the viewpoint of fluid flow theory, from a practical view point and in accordance to the aforementioned dimensional guidelines, the structure would be unsatisfactory and prone to failure because of walls that would be too thin (Dimensional Guideline 3). The current disclosure teaches instead that for the same ratio of channel depth to width, the distance between channels should be twice the channel width, not equal. Otherwise, a method other than chemical etching would be required. One such method is laser scoring. The present invention also sets requirements for channel dimensions for the specific case of pressurized channels.

Adherence to these Dimensional Guidelines and to standard industry practices regarding the processes employed in conjunction with these guidelines can result in thin-plate microchannel structures with channel depths of only 50 microns or more sandwiched inside a lamination of substrate and unpatterned plate measuring as little as 4 mils overall. Actual dimensions depend on the nature of the heat transfer fluid flowing through these channels, as well as on the desired heat-transfer performance goals. An example of a 10-mil lamination thin-plate microchannel structure containing 100-micron-deep channels with carbon dioxide flowing through under supercritical pressure is provide in Example 1. This thin-plate microchannel structure removed over 40 watts of heat from a 27×27-millimeter heat source that was in direct contact with it. Conditions such as this are exemplary of a cooling device for semiconductor chips that are mounted on a printed circuit board. In this case, the thin-plate microchannel structure can be mounted directly on the chip, or chip packaging, and in contact with it. It may even be within the board to remove residual heat.

### EXAMPLE 1

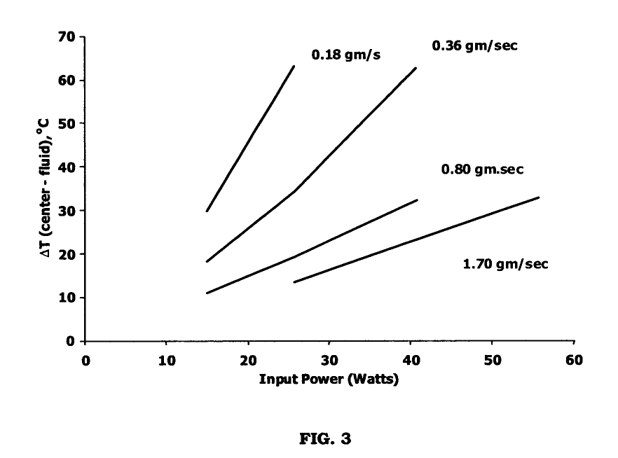

A thin-plate microchannel structure measuring 100×100 millimeters square and 0.010 inches in thickness is constructed with an array of 78 microchannels running across the center of the lamination, from one side to the opposite side. The channels measured nominally 200 microns wide by 100 microns deep and were separated by a distance of nominally 100 microns. In the center of the thin-plate microchannel structure was a heat source measuring 27×27 millimeters. Heat emitted by a heater was from 15-55 watts. Into this thin-plate microchannel structure was passed carbon dioxide at 84 bar and 37° C. inlet temperature, and at flow rates ranging between 0.18 and 1.70 gm per sec. As shown by the curves marked with a dotted line in FIG. 3, the temperature at the center of the heat source can be controlled to under 90° C. This corresponds to a temperature difference on the y-axis of FIG. 3 of about 53° C., at a CO₂ flow rate as low as approximately 0.5 gm/sec, given a heating rate of 40 watts. Pressure drop through the thin-plate microchannel structure is approximately 17 psi.

The example demonstrates heat-removal capability in tests involving a single heater, which simulates an integrated circuit or semiconductor chip. However, it is possible for a single run of microchannels to serve more than one device mounted to it. It is also possible to install more than one run of microchannels in a single thin-plate microchannel structure, thereby cooling separate groups of devices.

### EXAMPLE 2

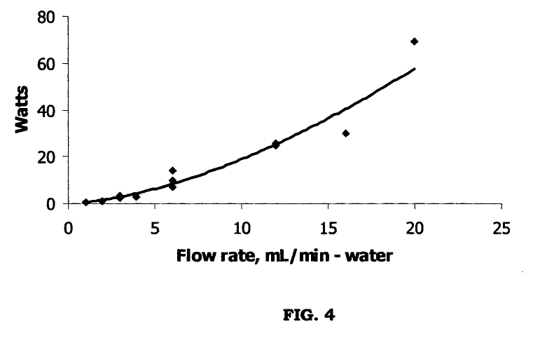

The same thin-plate microchannel heat exchanger was used to remove heat from a heat source measuring 27×27 mm in area, but with water as the cooling medium. Water flow rates of up to 20 mL/min absorbed up to 60 watts of heat, as shown in FIG. 4.

Edge connectors are just one type of device for passing fluid to and from a thin-plate microchannel structure. They have the advantage of taking up only a small amount of space in a direction perpendicular to the surface of the thin-plate microchannel structure, allowing installation to boards that are typically placed in slots on mounting racks. The ability to place the inlet and outlet either on opposite or adjacent sides provides extra flexibility in printed circuit board design. Connectors can also be mounted on the surface of a printed circuit board.

In the particular case of edge connectors, the microchannel pattern bleeds off the edges, leaving channel ends exposed. The connector is joined to the thin-plate microchannel structure in any suitable manner including, but not limited to, clamping or soldering. A connector may contain a header for distributing flow as evenly as possible to all of the microchannels in a group. A header is a widening of the flow path that allows flow from a single inlet tube or pipe to be distributed to many microchannels that are arranged in parallel; in other words, the header allows for a one-to-many distribution of flow at the inlet. At the outlet, the header servers to collect flow from the microchannel group in a many-to-one fashion. Such headers are positioned on the same plane as the thin-plate microchannel structure so as to minimize the overall thickness of the combined thin-plate microchannel structure and connector assembly.

We claim:

1. A thin-plate microchannel structure consisting of:
a two layers of material bonded together;
b microchannels of 500 microns or less;
c a total thickness that is less than 1.0 millimeter and;
d the capability of withstanding pressure up to 6,000 psi.

2. The thin-plate microchannel structure as in claim 1 wherein the thickness of said thin-plate microchannel structure measures no more than three times the depth of said microchannel.

3. The thin-plate microchannel structure as in claim 1 wherein said structure is formed from the combination of any two materials from the group consisting of metallic, ceramic, polymeric materials and a combination thereof.

4. The thin-plate microchannel structure as in claim 1 wherein connectors are incorporated to distribute and collect fluid flow.

5. A method of constructing a thin-plate microchannel structure consisting of:
a Forming a pattern of microchannel trenches on a substrate
b Bonding an unpatterned plate over the top of said patterned substrate.

6. The method as in claim 5 wherein trenches are formed in said substrate using a method from the group consisting of etching, pressing with an embossed pattern, machining, laser scoring, and a combination thereof.

7. The method as in claim 5 wherein said unpatterned plate is bonded to the top of said patterned substrate using a method from the group consisting of diffusion bonding, bonding with an adhesive interface, brazing with a flowable metallic interface, and a combination thereof.

8. The method as in claim 5 wherein the sum of the ratios of the depth of said microchannel to the width of said microchannel and the thickness of said unpatterned plate to the width of said microchannel is at least 1.

9. The method as in claim 5 wherein the ratio of the distance between said microchannels at the top surface of the patterned substrate to the depth of said microchannels is at least 0.5.

10. The method as in claim 5 wherein if a flowable interface is used then the ratio of the thickness of a flowable interface to the depth of said microchannel is no greater than 0.33.

11. The thin-plate microchannel structure as in claim 1 wherein the thin-plate microchannel structure is incorporated into a printed circuit board.

12. The thin-plate microchannel structure as in claim 1 wherein the thin-plate microchannel structure is incorporated into the packaging of an integrated circuit.

13. The thin-plate microchannel structure as in claim 1 wherein the thin-plate microchannel structure is incorporated into a computer casing.

14. The thin-plate microchannel structure as in claim 1 wherein the thin-plate microchannel structure is located near a device with which it is exchanging heat.

15. The thin-plate microchannel structure as in claim 1 wherein the thin-plate microchannel structure is in contact with a device with which it is exchanging heat.
